(19) United States
(12) Patent Application Publication
(10) Pub. No.: US 2009/0057860 A1
(43) Pub. Date: Mar. 5, 2009

(54) Semiconductor memory package

(75) Inventors: Seok Bae, Suwon-si (KR); Yul-Kyo Chung, Yongin-si (KR); Sung-Taek Lim, Suwon-si (KR); Hyung-Mi Jung, Suwon-si (KR); Yee-Na Shin, Seoul (KR); Seung-Hyun Sohn, Suwon-si (KR); Jin-Seok Moon, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/230,243

(22) Filed: Aug. 26, 2008

(30) Foreign Application Priority Data
Aug. 27, 2007 (KR) 10-2007-0086244

(51) Int. Cl. H01L 23/48

(52) U.S. Cl. 257/680; 257/E23.01

(57) ABSTRACT

Disclosed is a semiconductor memory package having a thin-film decoupling capacitor that reduces radio frequency noise. The semiconductor memory package in accordance with an embodiment of the present invention includes a substrate, a memory chip being mounted on one side of the substrate and a decoupling capacitor formed in the vicinity one the side of the substrate where the memory chip is mounted.

### CROSS-REFERENCE TO RELATED APPLICATIONS

This application claims the benefit of Korean Patent Application No. 10-2007-0086244, filed with the Korean Intellectual Property Office on Aug. 27, 2007, the disclosure of which is incorporated herein by reference in its entirety.

### BACKGROUND

1. Technical Field

The present invention relates to a semiconductor memory package, more particularly to a semiconductor memory package having a thin-film decoupling capacitor that reduces radio frequency noise.

2. Description of the Related Art

Memory cards are installed and used in not only desktop computers and laptop computers but also portable electronic devices, such as digital cameras, camcorders, MP3 players, Portable Multimedia Players (PMP), mobile phones and GPS navigation systems. While the increase in the amount of high-quality image data and high-quality sound data requires that data be read and written faster, the portability of these electronic devices demands the size of the memory card to be smaller. Accordingly, the width of circuits of a semiconductor memory is remarkably narrower than before, sometimes to two-digit nanometers (nm), and the operation speed has reached three-digit mega-hertz (MHz). When a circuit becomes this minute, the cross section of the circuit is so reduced that the resistance is increased at a voltage/current. Therefore, there have been efforts to reduce the resistance by decreasing the voltage.

As the importance of portability in many of today's electronic devices somewhat limit the battery capacity, it is important to minimize the energy consumption by employing a circuit having fundamentally little energy consumption and improving the efficiency of the circuit. However, as the portable electronic devices become more sophisticated with more functions, the electronic devices are increasingly using more electric power than ever before.

As an operating voltage is reduced with the progress of fine circuits, the margin of the operating voltage is also reduced, making the noise an important factor. Use of a low power, high speed circuit increases the maximum current and, consequently, a current variable ratio on the circuit, which becomes a main cause of the noise.

$$Δ V = iR + L \frac{d i}{d t} \qquad ( 1 )$$

Equation (1) signifies that a current (i) change depending on time (t) multiplied by an inductance (L) corresponds to a cause of a voltage fluctuation (ΔV).

When voltage is reduced at a constant electric power, current is increased. This implies an increase of the left term, iR, of the right side of Equation (1). Besides, as the circuit operates at a high speed and a logic element fully operates, there occurs a time when the maximum electric power is momentarily consumed. At this time, while di/dt increases, a parasitic inductance component generated due to the long length of the circuit wiring amplifies the noise. As a result, insufficient electric power is provided to every logic element, possibly malfunctioning the circuit.

Accordingly, a decoupling capacitor is formed between the ground voltage end and the power supply voltage end of the semiconductor memory. The decoupling capacitor is positioned near an IC circuit to reduce the noise and function as a compact battery, which supplies momentarily insufficient electric power at a closest distance.

The most used decoupling capacitor in the semiconductor memory package is the multilayer Ceramic Capacitor (MLCC) type. However, the MLCC has a high parasitic inductance due to the electrode stacked-structure and thus is little effective in removing the noise. Moreover, the low resonant frequency makes the MLCC ineffective as a decoupling capacitor at a frequency above a few hundred mega hertz (MHz). Also, since the MLCC is a discrete type device, it has a discrete capacity value, leaving very little room to choose a proper capacity value.

### SUMMARY

The present invention provides a semiconductor memory package having a parasitic inductance minimized in an electrode structure by using a decoupling capacitor in the form of a thin film.

The present invention also provides a semiconductor memory package having both an excellent property of removing RF noise and a wideband that can be used.

The present invention also provides a semiconductor memory package having a thin film type of decoupling capacitor by reducing the thickness, and eliminating the possibility of a passive element being separated by an external force during the manufacturing or handling of a product implementing the semiconductor memory package.

An aspect of the present invention features a semiconductor memory package. The semiconductor memory package in accordance with an embodiment of the present invention can include: a substrate; a memory chip configured to be mounted on one side of the substrate; and a decoupling capacitor formed in the vicinity of an area on the side of the substrate where the memory chip is mounted

The memory chip can be wire-bonded to substrate wiring formed on the other side of the substrate through a window formed on the substrate.

The decoupling capacitor can be a thin film type.

The decoupling capacitor can have a single layer structure. The decoupling capacitor can include a dielectric thin film between a first metal electrode film and a second metal electrode film. At least one of the first metal electrode film and the second metal electrode film is made of one of a metal, a metal alloy, a conductive metal oxide, a conductive polymer material and a conductive composite material selected from a group consisting of Cu, Al, Ni, Ag, Au, Pt, Sn, Pb, Ti, Cr, Pd, In, Zn and C.

The decoupling capacitor can have a multi layer structure. The decoupling capacitor can include two or more dielectric thin films between a lower electrode and an upper electrode, and an intermediate electrode is disposed between the dielectric thin films. At least one of the upper electrode, the lower electrode and the intermediate electrode is made of one of a metal, a metal alloy, a conductive metal oxide, a conductive polymer material and a conductive composite material selected from a group consisting of Cu, Al, Ni, Ag, Au, Pt, Sn, Pb, Ti, Cr, Pd, In, Zn and C.

The dielectric thin film can be made of amorphous metal oxide of BiZnNb series.

Another aspect of the present invention features a semiconductor memory package. The semiconductor memory package in accordance with an embodiment of the present invention can include: a substrate; a decoupling capacitor configured to be formed in the vicinity of a window on one side of the substrate; and a memory chip configured to be mounted on the decoupling capacitor.

The memory chip can be wire-bonded to substrate wiring formed on the other side of the substrate through the window.

Also, the decoupling capacitor can be in a thin film type.

The decoupling capacitor can have a single layer structure. The decoupling capacitor can include a dielectric thin film between a first metal electrode film and a second metal electrode film at least one of the first metal electrode film and the second metal electrode film is made of one of a metal, a metal alloy, a conductive metal oxide, a conductive polymer material and a conductive composite material selected from a group consisting of Cu, Al, Ni, Ag, Au, Pt, Sn, Pb, Ti, Cr, Pd, In, Zn and C.

The decoupling capacitor can have a multi layer structure. The decoupling capacitor can include two or more dielectric thin films between a lower electrode and an upper electrode, and an intermediate electrode is disposed between the dielectric thin films. At least one of the upper electrode, the lower electrode and the intermediate electrode is made of one of a metal, a metal alloy, a conductive metal oxide, a conductive polymer material and a conductive composite material selected from a group consisting of Cu, Al, Ni, Ag, Au, Pt, Sn, Pb, Ti, Cr, Pd, In, Zn and C.

The dielectric thin film can be made of amorphous metal oxide of BiZnNb series.

### BRIEF DESCRIPTION OF THE DRAWINGS

FIG. 1 illustrates a cross sectional view of a semiconductor memory package having a decoupling capacitor having a single layer structure according to an embodiment of the present invention.

FIG. 2 illustrates a cross sectional view of a semiconductor memory package having a decoupling capacitor having a multi layer structure according to another embodiment of the present invention.

FIG. 3 illustrates a cross sectional view of a semiconductor memory package having a decoupling capacitor according to yet another embodiment of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the spirit and scope of the present invention. In the following description of the present invention, the detailed description of known technologies incorporated herein will be omitted when it may make the subject matter unclear.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, certain embodiments of the present invention will be described in detain with reference to the accompanying drawings.

As a memory has a high operating speed and a high capacity, being employed is a Double Data Rate (DDR2: having a speed more than twice as fast as that of an SDR and a low operating voltage of 2.5V, consequently having low heat generation, unlike the SDR having an operating voltage of 3.3V) type. Since a DDR2 memory card includes a fine memory chip circuit and a fine BGA, it is difficult to directly mount the DDR2 memory card on a printed circuit board memory card, so that devised has been a method for packaging the memory chip in the form of a Chip on Board (COB) and then mounting the packaged memory chip on the printed circuit board memory card.

The COB has an open shape by processing a window in the middle of the inside of the substrate. In the COB, a pad of the memory chip is wire-bonded to a substrate wiring through the window. The COB employs the DDR2 type, thereby substituting an existing Thin Small Outline Package (TSOP), causing goods to be light, thin, short and small, and has excellent electric and thermal properties. Hereinafter, the following description will be focused on the COB among the semiconductor memory packages.

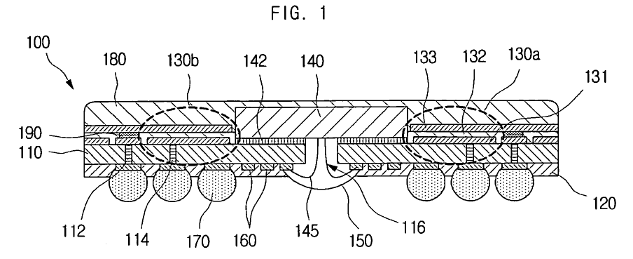

FIG. 1 illustrates a cross sectional view of a semiconductor memory package having a decoupling capacitor having a single layer structure according to an embodiment of the present invention. Here, single layer structure decoupling capacitors 130A and 130B are formed in a semiconductor memory package 100.

The semiconductor memory package 100 includes a substrate 110. A memory chip 140 is mounted on one side of the substrate 110. A substrate wiring 160, a solder ball 170 and a solder resist 120 are formed on the other side thereof.

The memory chip 140 is mounted on one side of the substrate 110. An adhesive layer 142 is formed between the memory chip 140 and the one side of substrate 110 so that the memory chip 140 is prevented from being separated from the substrate 110.

A window 116 is formed in the middle of the area where the memory chip 140 is mounted. In the memory chip 140, a pad of the memory chip 140 is wire-bonded to the substrate wiring 160 formed on the other side of the substrate 110 through the window by using a wire 145. The window 116 is electrically charged and the wire 145 is protected by using epoxy material 150.

The solder ball 170 is formed on the other side of the substrate 110 such that the semiconductor memory package 100 can be mounted on the printed circuit board memory card in the manner of BGA. The semiconductor memory package 100 transmits and receives an electrical signal to and from the printed circuit board memory card through the solder ball 170.

A plated through hole (PTH) and a blind via hole (BVH) 114 are formed on the substrate 110 so that one side and the other side of the substrate 110 are electrically connected to each other. The electrical signal transmitted from an external printed circuit board memory card through the solder ball 170 is transmitted to one side of the substrate 110.

The single layer structure decoupling capacitors 130A and 130B are formed in an area of one side of the substrate 110, the area being adjacent to the memory chip 140. Hereinafter, the following description will be focused on the single layer structure decoupling capacitor having a reference number of 130A.

The single layer structure decoupling capacitor 130A includes a first metal electrode film 131, a dielectric thin film 132 and a second metal electrode film 133. The first metal electrode film 131 is formed in the vicinity of an area where the memory chip 140 has been mounted, the area being in one side of the substrate 110. The first metal electrode film 131 can be made up of at least one metal or a metal alloy, a conductive metal oxide, conductive polymer material and conductive composite material, etc. selected from a group constituted by Cu, Al, Ni, Ag, Au, Pt, Sn, Pb, Ti, Cr, Pd, In, Zn and C. The first metal electrode film 131 can be formed through sputtering, evaporation or an electroless plating process and so on. The thickness of the first metal electrode film 131 can be from 10 to 20 μm

The dielectric thin film 132 is formed on the first metal electrode film 131. The dielectric thin film 132 is made up of paraelectric material or ferroelectric material. Preferably, the dielectric thin film 132 is made up of amorphous metal oxide of BiZnNb series, that is, paraelectric material having excellent high frequency characteristics. The amorphous metal oxide of BiZnNb series has a dielectric constant of at least 15, preferably, can have a dielectric constant of more than 30. Desirably, the dielectric thin film 132 employed in the present invention is a metal oxide represented by BiₓZn_{y}Nb_{z}O₇. In order that the dielectric thin film 132 can be employed as a thin film capacitor, the thickness of the dielectric thin film 132 can be preferably from 50 nm to 1 μm, and more preferably from 200 to 500 nm.

The second metal electrode film 133 is formed on the dielectric thin film 132. The second metal electrode film 133 can be formed of a material similar to the first metal electrode film 131 and be formed by a process similar to that of the first metal electrode film 131. The second metal electrode film 133 is formed only on the upper part of the dielectric thin film 132, not on the upper part of the memory chip 140.

The second metal electrode film 133 is electrically connected to the substrate wiring through a contact via 190.

The memory chip 140 is connected to the substrate wiring 160 through the pad and the wire 145. The memory chip 140 is electrically connected to the decoupling capacitors 130A and 130B through the substrate wiring 160, the PTH 112, the BVH 114, which have been formed on the substrate 110.

In order to prevent cases where a high current is required at the time when a logic element is operated in the memory chip 140, and where a voltage drop occurs due to the momentary increase of a current value, and where the logic element cannot operate at 100% capacity, the decoupling capacitors 130A and 130B adjacent to the memory chip 140 helps an electric current to be sufficiently supplied. A direct current (DC) is supplied to the memory chip 140. The DC removes noise from a radio frequency source of a peripheral circuit.

The semiconductor memory package 100 is completed by covering the decoupling capacitors 130A and 130B and the memory chip 140 mounted on the one side of the substrate 110 with an epoxy molding compound 180.

The epoxy molding compound 180 is a thermosetting resin sealant made by compounding an epoxy resin and several kinds of materials. The epoxy molding compound 180 is used to protect the memory chip 140 from external heat, moisture and impact and the like. It is preferable that the epoxy molding compound 180 is constituted by a molding material having a good thermal conductivity.

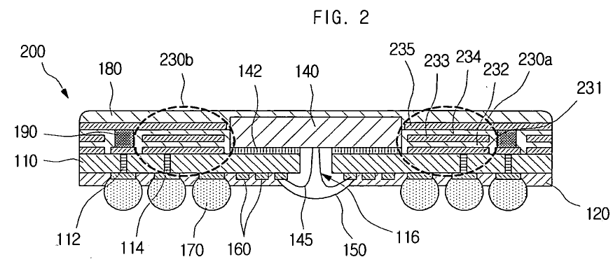

The single layer structure decoupling capacitor has been described in the foregoing description. But, when an electrostatic capacitance is not enough with the single layer structure decoupling capacitor, it is possible to increase the electrostatic capacitance approximately to an electrostatic capacitance of integer multiple by laminating at least two metal-insulator-metal (MIM) structures. This matter will be described with reference to FIG. 2.

FIG. 2 illustrates a cross sectional view of a semiconductor memory package having a decoupling capacitor having a multi layer structure according to another embodiment of the present invention. In the description with reference to FIG. 2, elements given the same reference numerals as those of FIG. 1 are the same or correspond to the elements of FIG. 1, and any redundant description of the identical or corresponding elements will not be repeated.

In the semiconductor memory package 200, a multi layer structure decoupling capacitors 230A and 230B are formed in an area adjacent to an area where the memory chip 140 has been mounted, the area being in one side of the substrate 110. Hereinafter, the following description will be focused on the multi layer structure decoupling capacitor having a reference number of 230A. While the following description will be focused on two layer structure decoupling capacitor, it should be understood by those skill in the art that more than three layer structure decoupling capacitor can be also applied in the same way.

The multi layer structure decoupling capacitors 230A includes a first metal electrode film 231, a first dielectric thin film 232, a second metal electrode film 233, a second dielectric thin film 234 and a third metal electrode film 235. The first metal electrode film 231 corresponds to a lower electrode. The third metal electrode film 235 corresponds to an upper electrode. An inter-electrode is located in each space among two or more dielectric thin films between the lower electrode and the upper electrode.

The lower electrode, i.e., the first metal electrode film 231 is formed in the vicinity of an area where the memory chip 140 has been mounted, the area being in one side of the substrate 110. The first metal electrode film 231 can be made up of at least one metal or a metal alloy, a conductive metal oxide, conductive polymer material and conductive composite material, etc. selected from a group constituted by Cu, Al, Ni, Ag, Au, Pt, Sn, Pb, Ti, Cr, Pd, In, Zn and C. The first metal electrode film 231 can be formed through sputtering, evaporation or an electroless plating process and so on. The thickness of the first metal electrode film 231 can be from 10 to 20 μm

The first dielectric thin film 232 is formed on the first metal electrode film 231. The first dielectric thin film 232 is made up of paraelectric material or ferroelectric material. Preferably, the first dielectric thin film 232 is made up of amorphous metal oxide of BiZnNb series, that is, paraelectric material having excellent high frequency characteristics. The amorphous metal oxide of BiZnNb series has a dielectric constant of at least 15, preferably, can have a dielectric constant of more than 30. Desirably, the first dielectric thin film 232 employed in the present invention is a metal oxide represented by BiₓZn_{y}Nb_{z}O₇. In order that the first dielectric thin film 232 can be employed as a thin film capacitor, the thickness of the first dielectric thin film 232 can be preferably from 50 nm to 1 μm, and more preferably from 200 to 500 nm.

The second metal electrode film 233 is formed on the first dielectric thin film 232. The second metal electrode film 233 can be formed of a material similar to the first metal electrode film 231 and be formed by a process similar to that of the first metal electrode film 231.

The second dielectric thin film 234 is formed on the second metal electrode film 233. The second dielectric thin film 234 can be formed of a material similar to the first dielectric thin film 232 and be formed by a process similar to that of the first dielectric thin film 232.

The upper electrode, i.e., the third metal electrode film 235 is formed on the second dielectric thin film 234. The third metal electrode film 235 can be formed of a material similar to the first metal electrode film 231 and/or the second metal electrode film 233, and be formed by a process similar to that of the first metal electrode film 231 and/or the second metal electrode film 233. The third metal electrode film 235 is formed only on the upper part of the second dielectric thin film 234, not on the upper part of the memory chip 140.

The third metal electrode film 235 is electrically connected to the substrate wiring through a contact via 190.

The memory chip 140 is connected to the substrate wiring 160 through the pad and the wire 145. The memory chip 140 is electrically connected to the decoupling capacitors 230A and 230B through the substrate wiring 160, the PTH 112, the BVH 114, which have been formed on the substrate 110.

It is possible to obtain enough electrostatic capacitance by using the multi layer structure decoupling capacitors 230A and 230B.

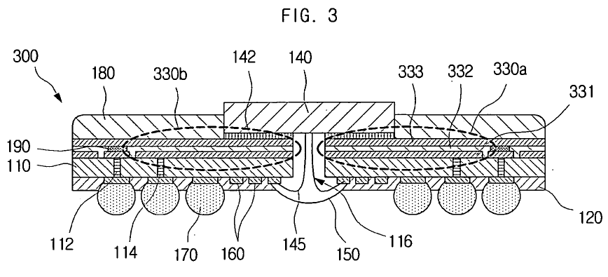

FIG. 3 illustrates a cross sectional view of a semiconductor memory package having a decoupling capacitor according to further another embodiment of the present invention. In the description with reference to FIG. 3, elements given the same reference numerals as those of FIG. 1 are the same or correspond to the elements of FIG. 1, and any redundant description of the identical or corresponding elements will not be repeated.

Decoupling capacitors 330A and 330B are formed on one side of the substrate 110. The memory chip 140 is mounted on the decoupling capacitors 330A and 330B. The adhesive layer 142 prevents the memory chip 140 from being separated. The decoupling capacitors 330A and 330B is formed in the vicinity of a window 116. The substrate wiring 160 formed on the other side of the substrate 110 is wire-bonded to the memory chip 140 through the window 116.

Hereinafter, the following description will be focused on the decoupling capacitor having a reference number of 330A. The decoupling capacitor 330A includes a first metal electrode film 331, a dielectric thin film 332 and a second metal electrode film 333.

The first metal electrode film 331 is formed in the vicinity of the window 116 in one side of the substrate 110. The first metal electrode film 331 can be made up of at least one metal or a metal alloy, a conductive metal oxide, conductive polymer material and conductive composite material, etc. selected from a group constituted by Cu, Al, Ni, Ag, Au, Pt, Sn, Pb, Ti, Cr, Pd, In, Zn and C. The first metal electrode film 331 can be formed through sputtering, evaporation or an electroless plating process and so on. The thickness of the first metal electrode film 331 can be from 10 to 20 μm.

The dielectric thin film 332 is formed on the first metal electrode film 331. The dielectric thin film 332 is made up of paraelectric material or ferroelectric material. Preferably, the dielectric thin film 332 is made up of amorphous metal oxide of BiZnNb series, that is, paraelectric material having excellent high frequency characteristics. The amorphous metal oxide of BiZnNb series has a dielectric constant of at least 15, preferably, can have a dielectric constant of more than 30. Desirably, the dielectric thin film 332 employed in the present invention is a metal oxide represented by BiₓZn_{y}Nb_{z}O₇. In order that the dielectric thin film 332 can be employed as a thin film capacitor, the thickness of the dielectric thin film 332 can be preferably from 50 nm to 1 μm, and more preferably from 200 to 500 nm.

The second metal electrode film 333 is formed on the dielectric thin film 332. The second metal electrode film 333 can be formed of a material similar to the first metal electrode film 331 and be formed by a process similar to that of the first metal electrode film 331. The second metal electrode film 333 is electrically connected to the substrate wiring through a contact via 190.

The memory chip 140 is connected to the substrate wiring 160 through the wire 145 passing through the window 116, and is electrically connected to the decoupling capacitors 330A and 330B through the substrate wiring 160, the PTH 112 and the BVH 114, which have been formed on the substrate 110.

Unlike the decoupling capacitors illustrated in FIGS. 1 and 2, the decoupling capacitors 330A and 330B are formed on the lower part of the memory chip 140. Since an area of the adhesive layer 142 of the memory chip 140 can be used as the area of the capacitor, the design flexibility of the electrostatic capacitance is increased. Also, while illustrated in FIG. 3 is only the decoupling capacitors 330A and 330B in the single layer structure, the decoupling capacitors 330A and 330B is applicable to the multi layer structure.

In the semiconductor memory packages 100 and 200 illustrated in FIGS. 1 and 2, after the memory chip 140 is mounted on one side of the substrate 110, the decoupling capacitors 130A, 130B, 230A and 230B are formed. On the contrary, in the semiconductor memory package 300 illustrated in FIG. 3, after the decoupling capacitors 330A, 330B are formed, the memory chip 140 is mounted.

In the case of the semiconductor memory package 300 illustrated in FIG. 3, because the decoupling capacitors 330A, 330B are located between the substrate 110 and the memory chip 140, the thickness of the semiconductor memory package 300 is increased. However, since the thickness of the decoupling capacitors 330A and 330B in the single layer is less than about 40 μm, that is, very small value compared with the whole size of the semiconductor memory package 300, the thickness of the decoupling capacitors 330A and 330B has little influence on the whole thickness of the semiconductor memory package 300.

While the present invention has been described focusing on exemplary embodiments thereof, it will be understood by those skilled in the art that various changes and modification in forms and details may be made without departing from the spirit and scope of the present invention as defined by the appended claims.

What is claimed is:

1. A semiconductor memory package comprising:
a substrate;
a memory chip configured to be mounted on one side of the substrate; and
a decoupling capacitor formed in the vicinity of an area on the side of the substrate where the memory chip is mounted.

2. The semiconductor memory package of claim 1, wherein the memory chip is wire-bonded to substrate wiring formed on the other side of the substrate through a window formed on the substrate.

3. The semiconductor memory package of claim 1, wherein the decoupling capacitor is a thin film type.

4. The semiconductor memory package of claim 1, wherein the decoupling capacitor has a single-layer structure.

5. The semiconductor memory package of claim 4, wherein the decoupling capacitor comprises a dielectric thin film between a first metal electrode film and a second metal electrode film.

6. The semiconductor memory package of claim 5, wherein at least one of the first metal electrode film and the second metal electrode film is made of one of a metal, a metal alloy, a conductive metal oxide, a conductive polymer material and a conductive composite material selected from a group consisting of Cu, Al, Ni, Ag, Au, Pt, Sn, Pb, Ti, Cr, Pd, In, Zn and C.

7. The semiconductor memory package of claim 1, wherein the decoupling capacitor has a multi-layer structure.

8. The semiconductor memory package of claim 7, wherein the decoupling capacitor comprises two or more dielectric thin films between a lower electrode and an upper electrode, and an intermediate electrode is disposed between the dielectric thin films.

9. The semiconductor memory package of claim 8, wherein at least one of the upper electrode, the lower electrode and the intermediate electrode is made of one of a metal, a metal alloy, a conductive metal oxide, a conductive polymer material and a conductive composite material selected from a group consisting of Cu, Al, Ni, Ag, Au, Pt, Sn, Pb, Ti, Cr, Pd, In, Zn and C.

10. The semiconductor memory package of claim 5, wherein the dielectric thin film is made of amorphous metal oxide of BiZnNb series.

11. The semiconductor memory package of claim 8, wherein the dielectric thin film is made of amorphous metal oxide of BiZnNb series.

12. A semiconductor memory package comprising:
a substrate;
a decoupling capacitor configured to be formed in the vicinity of a window on one side of the substrate; and
a memory chip configured to be mounted on the decoupling capacitor.

13. The semiconductor memory package of claim 12, wherein the memory chip is wire-bonded to substrate wiring formed on the other side of the substrate through the window.

14. The semiconductor memory package of claim 12, wherein the decoupling capacitor is in a thin film type.

15. The semiconductor memory package of claim 12, wherein the decoupling capacitor has a single layer structure.

16. The semiconductor memory package of claim 15, wherein the decoupling capacitor comprises a dielectric thin film between a first metal electrode film and a second metal electrode film.

17. The semiconductor memory package of claim 16, wherein at least one of the first metal electrode film and the second metal electrode film is made of one of a metal, a metal alloy, a conductive metal oxide, a conductive polymer material and a conductive composite material selected from a group consisting of Cu, Al, Ni, Ag, Au, Pt, Sn, Pb, Ti, Cr, Pd, In, Zn and C.

18. The semiconductor memory package of claim 12, wherein the decoupling capacitor has a multi-layer structure.

19. The semiconductor memory package of claim 18, wherein the decoupling capacitor comprises two or more dielectric thin films between a lower electrode and an upper electrode, and an intermediate electrode is disposed between the dielectric thin films.

20. The semiconductor memory package of claim 19, wherein at least one of the upper electrode, the lower electrode and the intermediate electrode is made of one of a metal, a metal alloy, a conductive metal oxide, a conductive polymer material and a conductive composite material selected from a group consisting of Cu, Al, Ni, Ag, Au, Pt, Sn, Pb, Ti, Cr, Pd, In, Zn and C.

21. The semiconductor memory package of claim 16, wherein the dielectric thin film is made of amorphous metal oxide of BiZnNb series.

22. The semiconductor memory package of claim 19, wherein the dielectric thin film is made of amorphous metal oxide of BiZnNb series.
